(19) United States
(12) Patent Application Publication
(10) Pub. No.: US 2004/0104388 A1
(43) Pub. Date: Jun. 3, 2004

(54) PIXEL STRUCTURE AND THIN FILM TRANSISTOR ARRAY USED IN LIQUID CRYSTAL DISPLAY

(76) Inventor: Meng-Yi Hung, Taoyuan Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,367

(22) Filed: Apr. 3, 2003

(30) Foreign Application Priority Data
Dec. 3, 2002 (TW) 91134999

(51) Int. Cl. H01L 29/04

(52) U.S. Cl. 257/59

(57) ABSTRACT

A pixel structure and a thin film transistor (TFT) array are provided. The TFT array consists of a first patterned conductive layer with scan lines, a first dielectric layer, channel layers, a second patterned conductive layer with data lines and source/drain, a second dielectric layer and pixel electrodes, wherein the first patterned conductive layer is on a substrate. The first dielectric layer is located on the substrate and covered the first patterned conductive layer. The channel layers are located on the first dielectric layer above the scan lines. The second patterned conductive layer is on the first dielectric layer and source/drain is located on the scan lines beside the channel layers. The second dielectric layer is on the first dielectric layer and covered the second patterned conductive layer. The pixel electrodes is located on the second dielectric layer, wherein the pixel electrodes connect with one end of the source/drain and the other end of the source/drain connects with the data lines.

### CROSS REFERENCE TO RELATED APPLICATIONS

This application claims the priority benefit of Taiwan application serial no. 91134999, filed Dec. 3, 2002.

### BACKGROUND OF INVENTION

1. Field of Invention

The present invention generally relates to a pixel structure and a thin film transistor (TFT) array for a liquid crystal display (LCD), and more particularly, to a pixel structure that is able to reduce the variance of the gate-drain capacitance (Cgd) in the TFT and a TFT array.

2. Description of Related Art

LCD as one kind of the panel displays has advantages of high picture quality, small size, light weight, low driving voltage, low power consumption, and wide application range. Therefore, it is widely applied in the electronic or computer consumption products such as the small, medium size of portable TVs, mobile phones, palm coders, notebook computers, desktop displays, and projection TVs. The current development of LCD can be roughly divided into two categories: active matrix LCD and passive matrix LCD. Wherein, the active matrix LCD is more accepted to be the major product of next generation. In the active matrix LCD, the TFT formed directly on the pixel electrode or other active element is used to control the data write in of the LCD. Therefore, the TFT or other active element inside the LCD becomes one of the major topics of the industrial development.

FIG. 1A and FIG. 1B schematically shows a top view of a conventional pixel structure for the TFT array and its I-I″ sectional view, respectively. Referring to FIG. 1A and FIG. 1B, a conventional pixel structure formed on a substrate 100 consists of a first conductive layer 106 with a gate 102 and a scan line 104, a gate isolation layer 108, a channel layer 110, a second conductive layer 116 with a data line 112 and a source/drain 114, a protection layer 118, and a pixel electrode 120. Wherein, the first conductive layer 106 is located on the substrate 100. The gate isolation layer 108 is located on the substrate 100 and covers the first conductive layer 106. The channel layer 110 is located on the gate isolation layer 108 above the gate 102. The second conductive layer 116 is located on the gate isolation layer 108, and the source/drain 114 inside the second conductive layer 116 is located beside the channel layer 110. The protection layer 118 is located above the gate isolation layer 108 and covers the second conductive layer 116. Moreover, there is a contact window opening 122 inside the protection layer 118. The pixel electrode 120 is located on the protection layer 118, wherein the pixel electrode 120 is electrically connected with one end of the source/drain 114 (a drain end) via the contact window opening 122 mentioned above, and the other end of the source/drain 114 (a source end) is electrically connected with the data line 112.

In the conventional pixel structure, since the drain and the pixel electrode are electrically connected with each other, Cgd varies and depends on the impacts of (1) relative position between the drain and the gate; (2) relative position between the pixel electrode and the gate. Wherein, since the distance between the gate and the drain is less, and the area where the gate 102 overlaps the drain 124 varies due to the misalignment in the step-exposure process. Therefore, the Cgd variance is mostly impacted by the relative position between the drain and the gate. In the TFT array, the Cgd variance can easily cause the stitching block (shot mura) problem when it is use to display.

Furthermore, in the conventional pixel structure, when TFT is ineffective due to improper manufacture process control or other factors, the bright spot is generated in TFT that is very difficult to fix and further deteriorates display quality.

### SUMMARY OF INVENTION

To solve the problem mentioned above, it is an objective of the present invention to provide a pixel structure and a TFT array that can significantly improve the Cgd variance problem.

It is another objective of the present invention to provide a pixel structure and a TFT array that can easily weld the source end and the pixel electrode together so as to fix the bright spot problem.

In order to achieve the objectives mentioned above and others, a TFT array is provided. The TFT array consists of a first patterned conductive layer with scan lines, a first dielectric layer, channel layers, a second patterned conductive layer with data lines and a plurality of source/drain, a second dielectric layer and pixel electrodes, wherein the first patterned conductive layer is located on a substrate. The first dielectric layer is located on the substrate and covers the first patterned conductive layer. The channel layers are located on the first dielectric layer above the scan lines. The second patterned conductive layer is located on the first dielectric layer and the plurality of source/drain inside the second patterned conductive layer is located on the scan lines beside the channel layers. Moreover, the second dielectric layer is on the first dielectric layer and covers the second patterned conductive layer, and there are contact window openings in the second dielectric layer. The pixel electrodes are located on the second dielectric layer, wherein the pixel electrodes are electrically connected with one end of the source/drain (the drain end), and the other end of the source/drain (the source end) is electrically connected with the data lines.

The present invention further provides a pixel structure that consists of a scan line, a first dielectric layer, a channel layer, a conductive layer with a data line and a source/drain, a second dielectric layer, and a pixel electrode. Wherein, the scan line is located on a substrate. The first dielectric layer is located on the substrate and covers the scan line. The channel layer is located on the first dielectric layer above the scan line. The conductive layer is located on the first dielectric layer, and the source/drain inside the conductive layer is located on the scan line beside the channel layer. Moreover, the second dielectric layer is located on the first dielectric layer and covers the conductive layer, and there are contact window openings inside the second dielectric layer. The pixel electrode is located on the second dielectric layer, wherein the pixel electrode is electrically connected with one end of the source/drain (the drain end), and the other end of the source/drain (the source end) is electrically connected with the data line.

Since all source/drain inside the TFT array are located on the scan line according to the present invention, the gate-drain capacitance (Cgd) formed between the gate and the drain is not varied.

Furthermore, although Cgd is stilled formed on the pixel electrode and a portion used as a gate inside the scan line according to the present invention. However, since the distance from the pixel electrode to the portion used as the gate inside the scan line is rather far (when compared with the distance from the drain to the gate), the Cgd value between the pixel electrode and the gate is rather smaller, therefore the Cgd variance is smaller accordingly. In other words, even the Cgd between the pixel electrode and the gate is not a constant; its impact to the Cgd is not so significant.

Moreover, since the pixel electrode extends to the source/drain that is beside the channel layer according to the present invention, when some TFT inside the pixel structure is ineffective, the portion where the pixel electrode extends to can be cut off, so that the pixel electrode is separated from the drain, and a portion above the source where the pixel electrode extends to is also welded, so as to achieve the objective of fixing the bight spot problem.

Furthermore, since the source/drain inside the pixel structure according to the present invention is located on the scan line, the opening rate is much higher.

### BRIEF DESCRIPTION OF DRAWINGS

The accompanying drawings are included to provide a further understanding of the invention, and are incorporated in and constitute a part of this specification. The drawings illustrate embodiments of the invention, and together with the description, serve to explain the principles of the invention. In the drawings,

FIG. 1A and FIG. 1B schematically shows a top view of a conventional pixel structure for the TFT array and its I-I″ sectional view, respectively; and

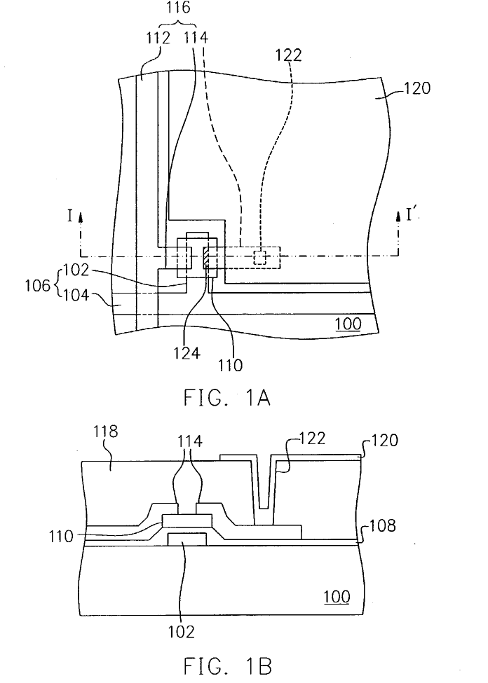

FIG. 2A and FIG. 2B schematically shows a top view of a pixel structure for the TFT array of a preferred embodiment according to the present invention and its I-I″ sectional view, respectively.

### DETAILED DESCRIPTION

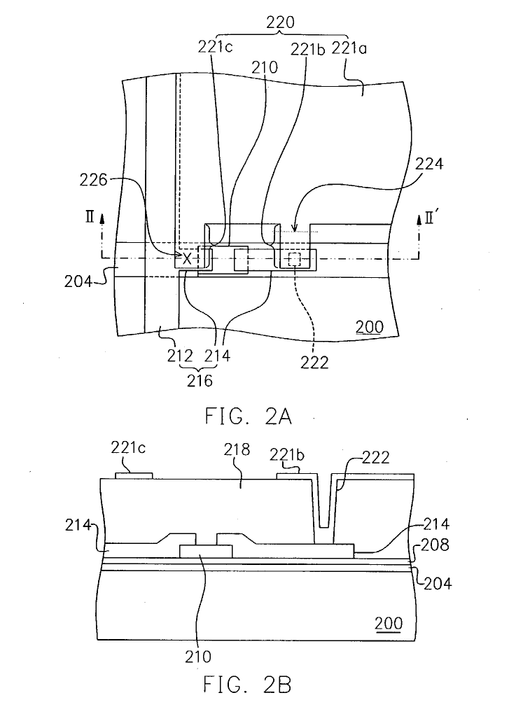

The present invention can be applied in a TFT array, wherein each pixel structure is as shown in FIG. 2A and FIG. 2B.

FIG. 2A and FIG. 2B schematically shows a top view of a pixel structure for the TFT array of a preferred embodiment according to the present invention and its I-I″ sectional view, respectively. Referring to FIG. 2A and FIG. 2B, the pixel structure consists of a first patterned conductive layer with scan lines 204, a first dielectric layer 208, a channel layer 210, a second patterned conductive layer 216 with a data line 212 and source/drain 214, a second dielectric layer 218, and a pixel electrode 220.

Keep referring to FIG. 2A and FIG. 2B, the scan lines 204 for each portion mentioned above are located on a substrate 200. The first dielectric layer 208 is located on the substrate 200 and covers the scan lines 204. The channel layer 210 is located on the first dielectric layer 208 above the scan lines 204. The second patterned conductive layer 216 is located on the first dielectric layer 208, and the source/drain inside the second patterned conductive layer 216 is located on the scan lines 204 beside the channel layer 210. The second dielectric layer 218 is located on the first dielectric layer 208 and covers the second patterned conductive layer 216. Moreover, there is a contact window opening 222 inside the second dielectric layer 218. The pixel electrode 220 is located on the second dielectric layer 218, wherein the pixel electrode 220 is electrically connected with one end of the source/drain 214 (the drain end) via the contact window opening 222 mentioned above, and the other end the source/drain (the source end) is electrically connected with the data line 212.

Moreover, in the present embodiment, the scan lines 204 extend along with a direction perpendicular to the extension direction of the data line 212, and there is a contact window opening 222 inside the second dielectric layer 218, so that the pixel electrode 220 can electrically connect with the source/drain 214. When the present invention is applied to a TFT array, since the TFT array has multiple pixel structures, the extension direction of each of the scan lines 204 is in parallel with each other, and the extension direction of each data line 212 is also in parallel with each other.

Please referring to FIG. 2A and FIG. 2B, the pixel electrode of the present embodiment comprises a display block 221 a, an optional electric-contacted block 221b that is extruded from the display block 221a, and the other optional fix-preparation block 221c that is extruded from the display block 221a and located above the source/drain 214. Wherein, the electric-contacted block 221b is used to electrically connect the pixel electrode 220 with the source/drain 214. When some TFT in the pixel structure is ineffective, the electric-contacted block 221b above the drain 214 where the pixel electrode 220 extends to can be cut off from the cutting line 224 with some facility like a laser beam, so that the pixel electrode 220 is separated from the drain 214, and a welding point 226 inside the fix-preparation block 221c above the source 214 where the pixel electrode 220 is extended to is welded, so as to achieve the objective of fixing the bright spot problem.

In summary, the present invention at least has following advantages:

1. Since all source/drain inside the TFT array are located on the scan line according to the present invention, the value of Cgd formed between the gate and the drain is almost kept as a constant.

2. Although Cgd is stilled formed on the pixel electrode and a portion used as a gate inside the scan line according to the present invention. However, since the distance from the pixel electrode to the portion used as the gate inside the scan line rather far (when compared with the distance from the drain to the gate), the Cgd value between the pixel electrode and the gate is rather smaller, therefore the Cgd variance is smaller accordingly. In other words, even the Cgd between the pixel electrode and the gate is not a constant; its impact to the Cgd is not so significant.

3. Since the pixel electrode extends to the source/drain that is beside the channel layer according to the present invention, when some TFT inside the pixel structure is ineffective, the portion where the pixel electrode extends to can be cut off, so that the pixel electrode is separated from the drain, and a portion above the source where the pixel electrode extends to is also welded, so as to achieve the objective of fixing the bight spot problem.

4. Since the source/drain inside the pixel structure according to the present invention is located on the scan line, the opening rate is much higher.

Although the invention has been described with reference to a particular embodiment thereof, it will be apparent to one of the ordinary skill in the art that modifications to the described embodiment may be made without departing from the spirit of the invention. Accordingly, the scope of the invention will be defined by the attached claims not by the above detailed description.

1. A TFT array, located on a substrate, comprising:
a first patterned conductive layer, located on the substrate, wherein the first patterned conductive layer comprises a plurality of scan lines;
a first dielectric layer, located on the substrate and covered the first patterned conductive layer;
a plurality of channel layers, located on the first dielectric layer, wherein the channel layers are located on the scan lines;
a second patterned conductive layer, located on the first dielectric layer, comprising a plurality of data lines and a plurality of source/drain, wherein the source/drain are located on the scan lines beside the channel layers;
a second dielectric layer, located on the second patterned conductive layer; and
a plurality of pixel electrodes, located on the second dielectric layer, wherein the pixel electrodes are electrically connected with one end of the source/drain, and the other end of the source/drain is electrically connected with the data lines.

2. The TFT array of claim 1, wherein the scan lines extend along with an extension direction in parallel.

3. The TFT array of claim 1, wherein the data lines extend along with an extension direction in parallel.

4. The TFT array of claim 1, wherein the scan lines extend along with a direction perpendicular to an extension direction of the data lines.

5. The TFT array of claim 1, wherein the second dielectric layer has a plurality of contact window openings, so that the pixel electrodes are electrically connected with the source/drain.

6. The TFT array of claim 5, wherein each of the pixel electrodes comprises:
a display block; and
an electric-contacted block, wherein the electric-contacted block is extruded from the display block, so that the pixel electrodes are electrically connected with the source/drain.

7. The TFT array of claim 5, wherein each of the pixel electrodes comprises:
a display block; and
an electric-contacted block, wherein the electric-contacted block is extruded from the display block, so that the pixel electrodes are electrically connected with the source/drain; and
a fix-preparation block, wherein the fix-preparation block is extruded from the display block, and the fix-preparation block is located on the source/drain.

8. A pixel structure, located on a substrate, comprising:
a scan line, located on the substrate;
a first dielectric layer, located on the substrate and covered the scan line;
a channel layer, located on the first dielectric layer, wherein the channel layer is located on the scan line;
a conductive layer, located on the first dielectric layer, comprising a data line and a source/drain, wherein the source/drain is located on the scan line beside the channel layer;
a second dielectric layer, located on the conductive layer; and
a pixel electrode, located on the second dielectric layer, wherein the pixel electrode is electrically connected with one end of the source/drain, and the other end of the source/drain is electrically connected to the data line.

9. The pixel structure of claim 8, wherein the scan line extends along with a direction perpendicular to an extension direction of the data line.

10. The pixel structure of claim 8, wherein the second dielectric layer has a contact window opening, so that the pixel electrode is electrically connected with one end of the source/drain.

11. The pixel structure of claim 10, wherein the pixel electrode comprises:
a display block; and
an electric-contacted block, wherein the electric-contacted block is extruded from the display block, so that the pixel electrode is electrically connected with the source/drain.

12. The pixel structure of claim 10, wherein the pixel electrode comprises:
a display block; and
an electric-contacted block, wherein the electric-contacted block is extruded from the display block, so that the pixel electrode is electrically connected with the source/drain; and
a fix-preparation block, wherein the fix-preparation block is extruded from the display block, and the fix-preparation block is located on the source/drain.
